(19) United States
(12) Patent Application Publication
(10) Pub. No.: US 2013/0307032 A1
(43) Pub. Date: Nov. 21, 2013

(54) METHODS OF FORMING CONDUCTIVE CONTACTS FOR A SEMICONDUCTOR DEVICE

(71) Applicants: Vimal Kamineni, Albany, NY (US); Ruilong Xie, Albany, NY (US)

(72) Inventors: Vimal Kamineni, Albany, NY (US); Ruilong Xie, Albany, NY (US)

(73) Assignee: GLOBALFOUNDRIES INC., Grand Cayman (KY)

(21) Appl. No.: 13/473,284

(22) Filed: May 16, 2012

(51) Int. Cl. H01L 29/78; H01L 23/48; H01L 21/768

(52) U.S. Cl. 257/288; 438/674; 257/770; 257/E21.575; 257/E29.255; 257/E23.01

(57) ABSTRACT

One illustrative method disclosed herein involves forming a contact opening in a layer of insulating material, forming a layer of conductive material above the layer of insulating material that overfills the contact opening, performing at least one chemical mechanical polishing process to remove portions of the conductive material positioned outside of the contact opening and thereby define a conductive contact positioned in the contact opening and, after performing the chemical mechanical polishing process, performing a selective metal deposition process to selectively form additional metal material on an upper surface of the conductive contact.

### BACKGROUND OF THE INVENTION

1. Field of the Invention

Generally, the present disclosure relates to the manufacture of sophisticated semiconductor devices, and, more specifically, to various methods of forming conductive contacts for a semiconductor device, such as a transistor, and a device incorporating such conductive contacts.

2. Description of the Related Art

The fabrication of advanced integrated circuits, such as CPU's, storage devices, ASIC's (application specific integrated circuits) and the like, requires the formation of a large number of circuit elements in a given chip area according to a specified circuit layout. Field effect transistors (NMOS and PMOS transistors) represent one important type of circuit element that, to a great extent, substantially determines the performance capability of integrated circuit devices employing such transistors. A field effect transistor, irrespective of whether an NMOS transistor or a PMOS transistor is considered, typically comprises so-called PN junctions that are formed by an interface of highly doped regions, referred to as drain and source regions, with a slightly doped or non-doped region, such as a channel region, disposed between the highly doped source/drain regions.

In a field effect transistor, the conductivity of the channel region, i.e., the drive current capability of the conductive channel, is controlled by a gate electrode formed adjacent to the channel region and separated therefrom by a thin gate insulation layer. The conductivity of the channel region, upon formation of a conductive channel due to the application of an appropriate control voltage to the gate electrode, depends on, among other things, the dopant concentration, the mobility of the charge carriers and, for a given extension of the channel region in the transistor width direction, the distance between the source and drain regions, which is also referred to as the channel length of the transistor. Thus, in modern ultra-high density integrated circuits, device features, like the channel length, have been steadily decreased in size to enhance the performance of the semiconductor device and the overall functionality of the circuit.

However, the ongoing shrinkage of feature sizes on transistor devices causes certain problems that may at least partially offset the advantages that may be obtained by reduction of the device features. Generally, decreasing the size of, for instance, the channel length of a transistor typically results in higher drive current capabilities and enhanced switching speeds. Upon decreasing channel length, however, the pitch between adjacent transistors likewise decreases, thereby limiting the size of the conductive contact elements—e.g., those elements that provide electrical connection to the transistor, such as contact vias and the like—that may fit within the available real estate between adjacent transistors. Accordingly, the electrical resistance of conductive contact elements becomes a significant issue in the overall transistor design, since the cross-sectional area of these elements is correspondingly decreased. Moreover, the cross-sectional area of the contact vias, together with the characteristics of the materials they comprise, may have a significant influence on the effective electrical resistance and overall performance of these circuit elements.

Thus, improving the functionality and performance capability of various metallization systems has become important in designing modern semiconductor devices. One example of such improvements is the enhanced use of copper metallization systems in integrated circuit devices and the use of so-called “low-k” dielectric materials (materials having a dielectric constant less than 3) in such devices. Copper metallization systems exhibit improved electrical conductivity as compared to, for example, prior art metallization systems using aluminum for the conductive lines and vias. The use of low-k dielectric materials also tends to improve the signal-to-noise ratio (S/N ratio) by reducing crosstalk as compared to other dielectric materials with higher dielectric constants. However, the use of such low-k dielectric materials can be problematic as they tend to be less resistant to metal migration as compared to some other dielectric materials.

Copper is a material that is difficult to etch using traditional masking and etching techniques. Thus, conductive copper structures, e.g., conductive lines or vias, in modern integrated circuit devices are typically formed using known single or dual damascene techniques. In general, the damascene technique involves: (1) forming a trench/via in a layer of insulating material; (2) depositing one or more relatively thin barrier layers; (3) forming copper material across the substrate and in the trench/via; and (4) performing a chemical mechanical polishing process to remove the excess portions of the copper material and the barrier layer positioned outside of the trench/via to define the final conductive copper structure. The copper material is typically formed by performing an electrochemical copper deposition process after a thin conductive copper seed layer is deposited by physical vapor deposition on the barrier layer

FIGS. 1A-1D depict one illustrative prior art process flow for forming conductive contact structures on an illustrative prior art transistor device 10. The transistor 10 is intended to be representative in nature. The transistor 10 is formed in an active region defined in a semiconducting substrate 11 by illustrative shallow trench isolation regions 13. In general, the transistor 10 is comprised of a gate insulation layer 12, a gate electrode 14, sidewall spacers 16 and illustrative source/drain regions 15 that are formed in the active region of the substrate 11. Of course, as will be recognized by those skilled in the art, various aspects of a real-world transistor are not depicted in FIG. 1A, e.g., metal silicide contacts, etc. At the point of fabrication depicted in FIG. 1A, a layer of insulating material 18 has been formed above the device and a plurality of openings 20 for source/drain contacts and an opening 22 for a gate contact have been formed in the layer of insulating material 18. The openings 20, 22 may be formed using well-known photolithography and etching techniques.

Next, as shown in FIG. 1B, a layer of conductive material 24, e.g., tungsten, aluminum, etc., is formed so as to overfill the openings 20, 22. In some cases, one or more barrier layers (not shown) may be formed in the openings 20, 22 and on the upper surface of the layer of insulating material 18 prior to forming the layer of conductive material 24.

Thereafter, as shown in FIG. 1C, one or more chemical mechanical polishing (CMP) processes are performed on the device 10 to remove excess portions of the layer of conductive material 24 (and any barrier layers) that are positioned outside of the openings 20, 22. This process results in the formation of illustrative conductive contacts 24A-C. The contacts 24A and 24B are conductively coupled to the source/drain regions 15, while the contact 24C is conductively coupled to the gate electrode 14.

FIGS. 1C-1D depict one illustrative example of a problem that may be encountered when conductive copper structures are formed by performing an electroplating process to deposit bulk copper material. In general, CMP processes can be difficult to control due to a variety of reasons, uneven topology of the devices formed on the substrate 11, variations in the slurry used during such CMP processes, degradation of polishing pads used in such CMP processes, accumulation of removed material on the polishing pads during the CMP process, performance differences associated with each unique CMP tool, etc. Ideally, if everything goes as planned, the CMP process will result in the conductive contact having an upper surface 24U that is substantially planar with the upper surface 18U of the layer of insulating material 18, as depicted for the gate contact 24C. However, in some cases, the CMP process results in the conductive contact having a dished surface 24D, such as that depicted for the source/drain contact 24A, or a recessed surface 24R, such as that depicted for the source/drain contact 24B. Dishing and recessing of the conductive contacts occurs for a variety of reasons, such as those mentioned above with respect to the difficulty in controlling CMP processes in general. As a specific example, recessing of the contact may occur when the chemical aspect of the CMP process is too aggressive. Dishing and recessing of the conductive contacts can be very problematic as discussed more fully below.

As shown in FIG. 1D, a metallization layer 40 is formed above the device 10 in a layer of insulating material 21. The metallization layer 40 is generally comprised of conductive structures 26 and 28, e.g., copper, that are formed in the layer of insulating material 21 using traditional techniques, e.g., damascene techniques. In the depicted example, the conductive structure 26 has first and second portions (or vias) 26A, 26B that are adapted to be conductively coupled to the contacts 24A, 24C, respectively, while the conductive structure 28 has a first portion (or via) that is adapted to be conductively coupled to the source/drain contact 24B.

The interface 24S between the via 26B and the gate contact 24C depicts the idealized and preferred interface between the two conductive members, where there is intimate contact between the two structures across the full width of the via 26B. The via 26A is depicted as being slightly misaligned with the contact 24A, which can occur frequently, given the very small physical size of modern transistor devices and the very high packing densities of such transistor devices on integrated circuit products. As can be seen in FIG. 1D, due in part to the presence of the dished surface 24D, the interface 30 between the via 26A and the contact 24A is less than ideal. Such an illustrative interface 30 is sometimes referred to in the industry as a “weak” contact. Conductive structures that are conductively coupled to one another in such a manner as that depicted for the a weak interface 30 (or other similarly less than ideal interfaces) can be problematic in that, at a minimum, the electrical resistance of the overall structure increases due to the relatively small area contact between the contact 24A and the via 26A. Additionally, localized heating in the interface region 30 that is greater than anticipated by the design process may occur due to the small area contact between the contact 24A and the via 26A. In some cases, such a weak interface 30 may fail relatively quickly in operation.

With continuing reference to FIG. 1D, the recessing of the source/drain contact 24B during the CMP process causes the depicted open contact 32 situation where there is no conductive contact at all between the via 28A of the conductive structure 28 and the source/drain contact 24B. Obviously, such open contact situations result in immediate and complete device failure.

The present disclosure is directed to various methods of forming conductive contacts for a semiconductor device, such as a transistor, and a device incorporating such conductive contacts, that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming conductive contacts for a semiconductor device, such as a transistor, and a device incorporating such conductive contacts. One illustrative method disclosed herein involves forming a contact opening in a layer of insulating material, forming a layer of conductive material above the layer of insulating material that overfills the contact opening, performing at least one chemical mechanical polishing process to remove portions of the conductive material positioned outside of the contact opening and thereby define a conductive contact positioned in the contact opening and, after performing the chemical mechanical polishing process, performing a selective metal deposition process to selectively form additional metal material on an upper surface of the conductive contact.

Another illustrative method disclosed herein involves forming a layer of insulating material above a structure, wherein the structure includes a first conductive structure, forming a contact opening in the layer of insulating material, forming a layer of conductive material above the layer of insulating material that overfills the contact opening, performing at least one chemical mechanical polishing process to remove portions of the conductive material positioned outside of the contact opening and thereby define a conductive contact positioned in the contact opening that is conductively coupled to the first conductive structure and, after performing the chemical mechanical polishing process, performing a selective metal deposition process to selectively form additional metal material on an upper surface of the conductive contact. In some embodiments, the structure is a layer of insulating material and the first conductive structure is a metal structure, such as a metal line. In other examples, the structure is a semiconducting substrate and the first conductive structure is a doped region formed in the substrate, e.g., a source/drain region for a transistor.

One illustrative device disclosed herein includes a first layer of insulating material, a conductive contact positioned in the first layer of insulating material, a region of additional metal material positioned on at least a portion of an upper surface of said conductive contact, wherein the additional metal material has a rounded upper surface and a second layer of insulating material positioned above the first layer of insulating material.

Another illustrative device disclosed herein includes a transistor comprising a gate electrode and a plurality of source/drain regions formed in a semiconducting substrate, a first layer of insulating material formed above the gate electrode and the source/drain regions and a plurality of source/drain conductive contacts positioned in the first layer of insulating material, wherein each of the source/drain conductive contacts are conductively coupled to one of the source/drain regions. In this embodiment, the device further includes a gate conductive contact positioned in the first layer of insulating material that is conductively coupled to the gate electrode, a region of additional metal material formed on at least a portion of an upper surface of each of the source/drain conductive contacts and on at least a portion of an upper surface of the gate conductive contact, wherein each of the regions of additional metal material have a rounded upper surface and a second layer of insulating material positioned above the first layer of insulating material.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1D depict one illustrative prior art method of forming conductive contacts on a transistor device and various problems that may result from using such an illustrative methodology;

FIGS. 2A-2E depict one illustrative method disclosed herein for forming conductive contacts; and

FIG. 3 depicts an illustrative transistor device that includes conductive contacts as formed in accordance with one illustrative embodiment of the methods disclosed herein.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure is directed to various methods of forming conductive contacts on integrated circuit products and to products that contain such contacts. As will be readily apparent to those skilled in the art upon a complete reading of the present application, the present method is applicable to a variety of devices (e.g., planar devices and non-planar devices such as FinFETs) and technologies, e.g., NFET, PFET, CMOS, etc., and is readily applicable to a variety of integrated circuit products, including, but not limited to, ASIC's, logic devices, memory devices, etc. With reference to the attached drawings, various illustrative embodiments of the methods disclosed herein will now be described in more detail.

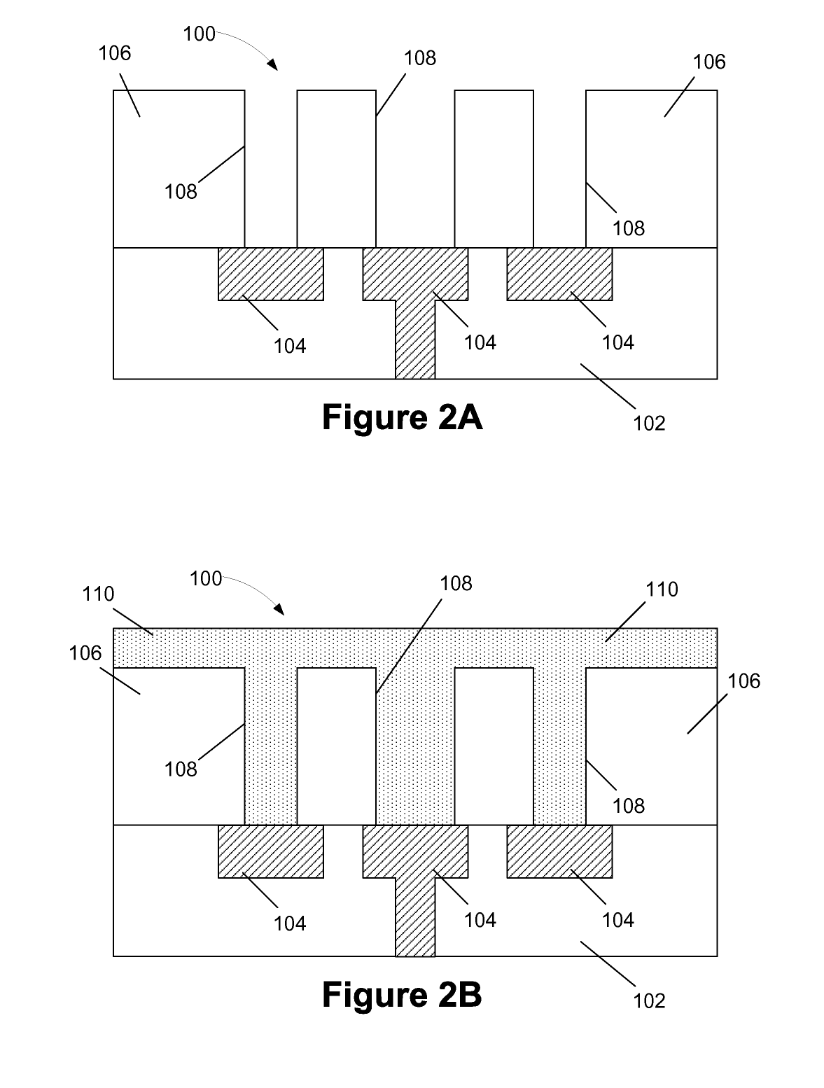

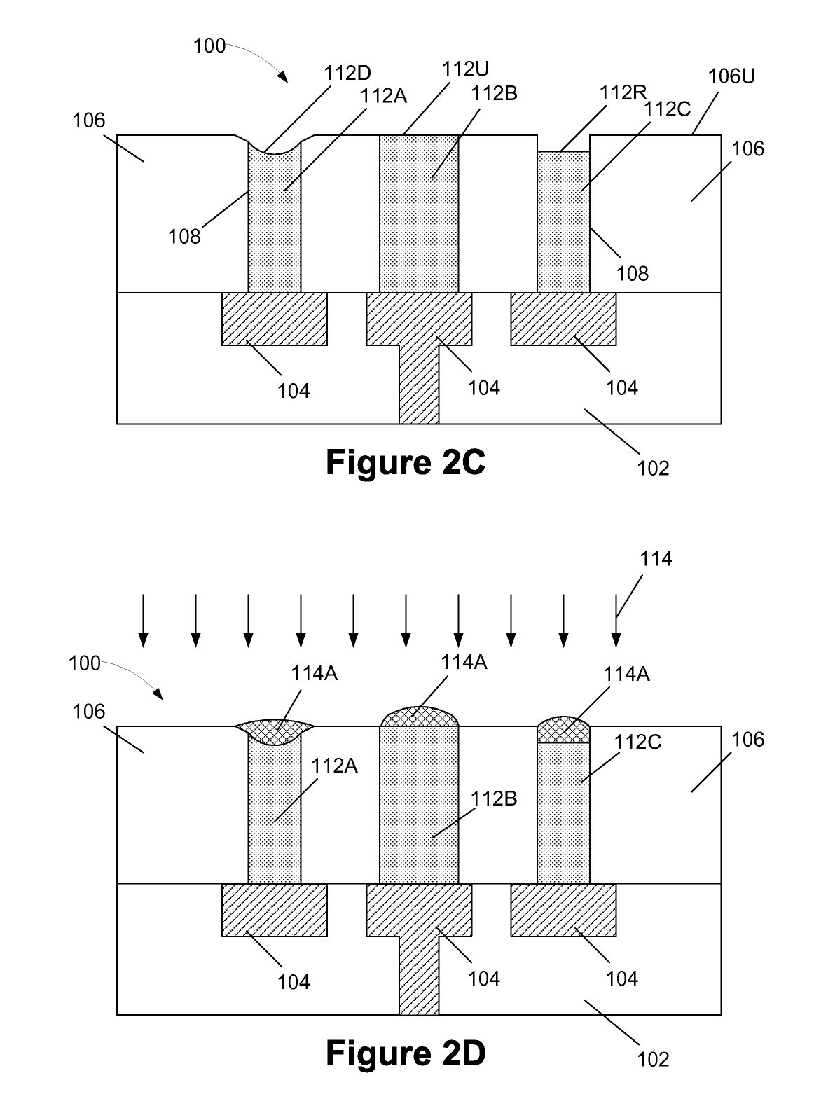

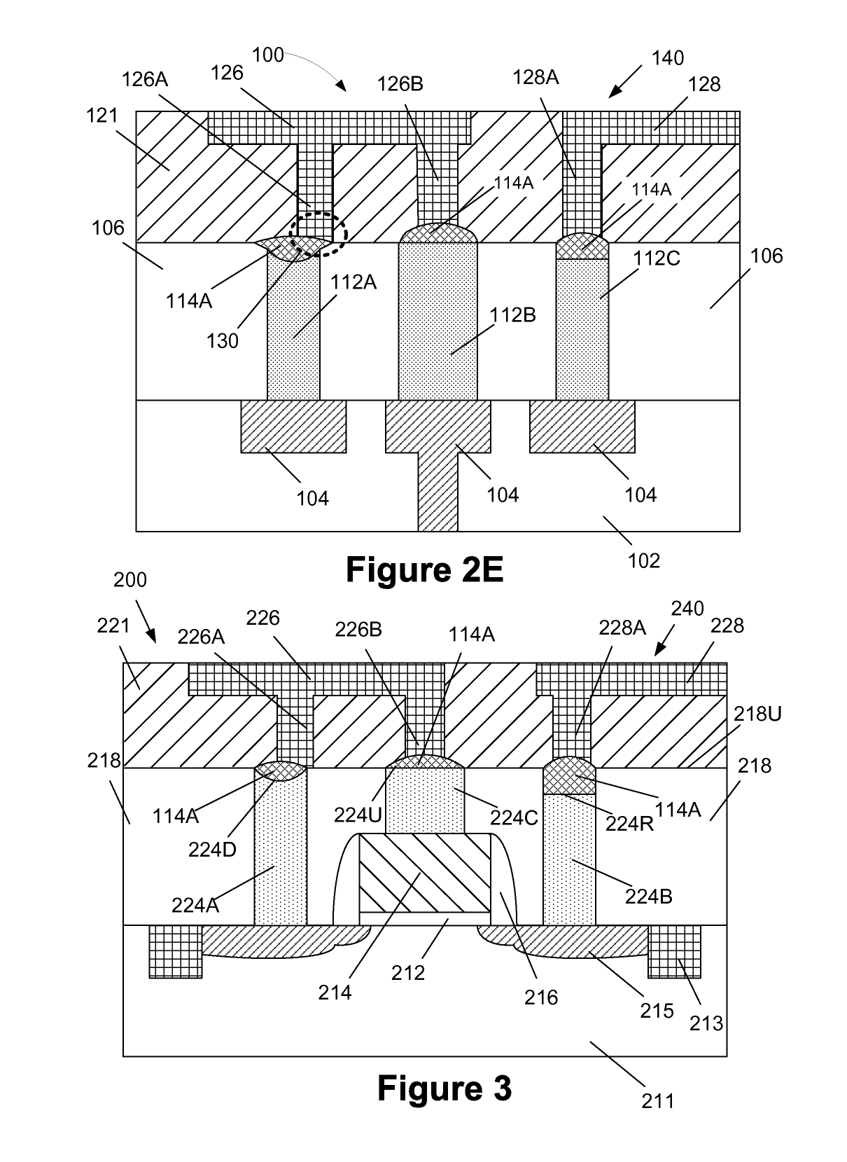

FIGS. 2A-2E depict various illustrative methods disclosed herein for forming conductive contacts that may be employed in a variety of applications as it relates to the fabrication of, for example, integrated circuit products. As will be appreciated by those skilled in the art after a complete reading of the present application, the methods disclosed herein may be employed to form conductive contacts at any level of a semiconductor device 100. That is, the methods disclosed herein may be employed to form conductive contacts that contact portions of an actual semiconductor device, e.g., contacts that are conductively coupled to the source/drain regions of a transistor or conductive contacts that contact a resistor structure formed in a semiconducting substrate. The methods disclosed herein may also be employed to form conductive contacts in any or all of the various wiring metallization layers that are typically found on integrated circuit products. Thus, the present inventions should not be considered to be limited to the formation of conductive contacts at any particular location or level of an integrated circuit product.

As shown in FIG. 2A, the integrated circuit device 100 comprises a structure 102 having one or more conductive structures 104 positioned or formed therein. As noted above, the presently disclosed inventions have broad application and, thus, the structure 102 is intended to be representative of any type of structure or layer of material, such as those that may be employed in manufacturing integrated circuit products. For example, the structure 102 may be a semiconducting substrate, a layer of insulating material (e.g., silicon dioxide, a layer of low-k insulating material (k value less than 3.5), etc.), and it may be positioned at any level of the integrated circuit device 100. Similarly, the conductive structures 104 are also intended to be representative in nature. For example, the conductive structures 104 may be traditional conductive contacts, e.g., metal lines/vias that are formed in a layer of insulating material. In one example, the conductive structures 104 may be comprised of a metal, such as tungsten, aluminum, copper, a metal silicide, etc. The conductive structures 104 may also represent a portion or the entirety of any type of structure or device that may be employed in manufacturing integrated circuit products. For example, the conductive structures 104 may be a doped region formed in a semiconducting substrate, such as a source/drain region for a transistor, a metal silicide layer that is formed on such a doped region, a resistor formed in a semiconducting substrate, a capacitor structure formed in a layer of insulating material, etc. Thus, the present inventions should not be considered to be limited to the formation of conductive contacts that are conductively coupled to any particular type of conductive structure 104 positioned in the structure 102. In general, the conductive structures 104 are any type of structure regardless of shape or composition for which it is desired to form a conductive contact that is conductively coupled to such a structure.

With continuing reference to FIG. 2A, a layer of insulating material 106 is formed above the structure 102 and a plurality of contact openings 108 are formed in the layer of insulating material 106. The contact openings 108 expose the conductive structures 104 in the structure 102. The layer insulating material 106 may be comprised of a variety of different materials, e.g., silicon dioxide, silicon nitride, silicon oxynitride, low-k insulating materials (k value less than 3.5), high-k insulating materials (k value greater than 10), etc., its thickness may vary depending upon the particular application, e.g., less than 100 nm, and it may be formed by a variety of techniques, e.g., chemical vapor deposition (CVD), physical vapor deposition (PVD), atomic layer deposition (ALD), etc. In one illustrative embodiment, the layer of insulating material 106 may be a layer of silicon dioxide that was formed by performing a CVD process. In some embodiments, the layer of insulating material 106 may actually be a multi-layer structure comprised of multiple layers of any of the forgoing insulating materials arranged in any desired configuration, e.g., an oxide/nitride/oxide stack. The contact openings 108 may be formed using traditional techniques, e.g., photolithography and etching. A etch mask that was used in forming the contact openings 108 is not depicted in FIG. 2A. The contact openings 108 may be of any desired size, shape and configuration. For example, the contact openings 108 may be line-type features or discreet rectangular, square or round shaped openings.

The next process operation involves the formation of conductive material that will eventually become the conductive contacts that will be positioned in the contact openings 108. More specifically, a layer of conductive material 110, e.g., a metal such as tungsten, aluminum, copper, cobalt, etc., is formed so as to overfill the openings 108 and contact the conductive structure 104. In some cases, one or more barrier layers (not shown) may be formed in the openings 108 and on the upper surface of the layer of insulating material 106 prior to forming the layer of conductive material 110. However, such barrier layers are not shown in the attached drawings so as to not obscure the present inventions. Moreover, it should be noted that the layer of conductive material 110 need not be the same material as that of the conductive structures 104 in the structure 102, although that configuration may occur in some applications. Thus, as far as materials of construction are concerned, the conductive structures 104 and the conductive contacts disclosed herein may have a variety of different material configurations, such as (the material of the conductive structures 104 being listed first in each of the following material parings): tungsten/copper, aluminum/copper, copper/copper, tungsten/tungsten, copper/tungsten, etc.

FIG. 2C depicts the device 100 after one or more chemical mechanical polishing (CMP) processes have been performed on the device 100 to remove excess portions of the layer of conductive material 110 (and any barrier layers) that are positioned outside of the openings 108. This process results in the formation of illustrative conductive contacts 112A-C that are conductively coupled to the conductive structures 104 in the structure 102. As noted in the background section of this application, in general, CMP processes can be difficult to control due to a variety of reasons which can cause the upper surface of the contacts 112A-C to have less than an ideal configuration. Ideally, if everything goes as planned, the CMP process will result in the conductive contact 112B having an upper surface 112U that is substantially planar with the upper surface 106U of the layer of insulating material 106. However, as noted previously, in some cases, the CMP process results in the conductive contact having a dished surface 112D, such as that depicted for the contact 112A, or a recessed surface 112R, such as that depicted for the contact 112B. The magnitude of the dishing and/or recessing may vary depending upon a variety of factors. For example, in some cases, the depth of the dished surface 112D (relative to the upper surface 106U of the layer of insulating material 106) may be about 1-5 nm (for narrow contact openings, e.g., trenches, but may be greater for wider contact openings), while the depth of the recessed surface 112R may be about 5-14 nm, but the depth of the recessed surface 112R may be greater if the CMP process uses a slurry with a strong chemical component.

Next, as shown in FIG. 2D, a selective metal deposition process 114 is performed that results in the formation of regions of additional metal material 114A on the exposed upper surfaces of the conductive contacts 112A-C. That is, the deposition process 114 is selective in that the regions of additional metal material 114A will only form on the exposed portions of the contacts 112A-C and such regions of additional metal material 114A will not form on the layer of insulating material 106. In one illustrative example, the regions of additional metal material 114A may have a rounded or bulged upper surface configuration, such as those depicted in the drawings. The regions of additional metal material 114A are depicted in a different cross-hatching to reflect the fact that they consist of material added to the contacts 112A after the CMP process has been performed, and to reflect that the regions of additional metal material 114A may be made of a material that has a different grain structure, e.g., a larger grain structure, than the grain structure of the material of the original conductive contacts 112A-C. The regions of additional metal material 114A need not be made of the same material as that of the conductive contacts 112A-C, although that configuration may occur in some applications. Thus, as far as materials of construction are concerned, the regions of additional metal material 114A and the conductive contacts 112A-C may have a variety of different material configurations, such as (the material of the conductive contacts 112A-C being listed first in each of the following material parings): tungsten/aluminum, aluminum/copper, copper/copper, tungsten/tungsten, copper/tungsten, etc.

The amount or quantity of the additional metal material 114A formed depends upon the magnitude of the dishing and/or recessing of the contacts 112A. In most cases, the regions of additional metal material 114A will be only a few nanometers thick, e.g., 1-5 nm. In some cases, the upper surface of the regions of additional metal material 114A may not extend above the upper surface 106U of the layer of insulating material 106 but it may in other situations. To the extent that the upper surface of the regions of additional metal material 114A does extend above the upper surface 106U of the layer of insulating material 106, the degree to which the regions of additional metal material 114A extends above the surface of the layer 106 will depend, in part, on the configuration of the upper surfaces of the underlying conductive contact 112A-C. For example, it would typically be expected that the amount of the additional metal 114A positioned above the contact 112B (with the substantially planar upper surface 112U (see FIG. 2C)) that extends above the upper surface 106U of the layer of insulating material 106 would be greater than that of the additional metal material 114A that is formed on the contacts 112A, 112C, due to the dished and recessed surfaces of the contacts 112A, 112C, respectively. In one illustrative embodiment, the selective metal deposition process 114 may be a selective CVD process that may be performed at a relatively low temperature, 300° C. or less, or at a relatively higher temperature, e.g., about 395° C. In one particularly illustrative example, the selective metal deposition process 114 may be the process that is believed to be described in U.S. Pat. No. 8,124,531 that is assigned to Novellus Systems, Inc., which is hereby incorporated by reference in its entirety. Various aspects of the methods disclosed in US Patent Publication No. 2010/0055904 (publication date of Mar. 4, 2010), which is also hereby incorporated by reference in its entirety, may also be employed when practicing aspects of the inventions disclosed herein. In some applications, it may be desirable to passivate the upper surface 106U of the layer of insulating material 106 prior to forming the additional metal material 114.

The process may proceed with deposition of tungsten-containing materials. In certain embodiments, formation of the additional metal material 114A may involve performing a chemical vapor deposition (CVD) process in which a tungsten-containing precursor is reduced by hydrogen to deposit tungsten. While tungsten hexafluoride (WF₆) is often used, the process may be performed with other tungsten precursors, including, but not limited to, tungsten hexachloride (WCl₆), organo-metallic precursors, and precursors that are free of fluorine, such as MDNOW (methylcyclopentadienyl-dicarbonyInitrosyl-tungsten) and EDNOW (ethylcyclopentadienyl-dicarbonyInitrosyl-tungsten). In addition, while hydrogen is generally used as the reducing agent in the CVD deposition of the bulk tungsten layer, other reducing agents including silane may be used in addition to or instead of hydrogen without departing from the scope of the invention. In one embodiment, a pulsed nucleation layer (PNL) technique may be employed in forming the tungsten layer. A nucleation layer is typically a thin conformal layer that facilitates subsequent deposition of bulk tungsten-containing material thereon. In a PNL technique, pulses of the reducing agent, purge gases, and tungsten-containing precursor are sequentially injected into and purged from the reaction chamber. The process is repeated in a cyclical fashion until the desired thickness is achieved. PNL broadly embodies any cyclical process of sequentially adding reactants for reaction on a semiconductor substrate, including atomic layer deposition (ALD) techniques. In another embodiment, tungsten hexacarbonyl (W(CO)₆) may be used with or without a reducing agent. Unlike with the PNL processes described above, in a CVD technique, the WF₆ and H₂ or other reactants are simultaneously introduced into the reaction chamber. This produces a continuous chemical reaction of mix reactant gases that continuously forms tungsten film on the substrate surface. According to various embodiments, the methods described herein are not limited to a particular method of partially filling a feature but may include any appropriate deposition technique. In one particularly illustrative embodiment, WF₆ and H₂ are employed as precursors and they react at a temperature of about 395° C. Since tungsten may be formed on any exposed portion of a so-called “glue” layer, such as titanium nitride in the case of a tungsten contact, and since any such glue layer would have been removed from above the surface 106U of the layer of insulating material 106 when the CMP process was performed (see FIG. 2C), the tungsten formed after the CMP process is performed may start growing on the remaining portions of the glue layer, e.g., on the remaining portions of a titanium nitride glue layer in the contact openings.

In performing the methods disclosed herein, in the case where actions are taken to passivate the upper surface 106U of the layer of insulating material 106, care should be taken to prevent excessive passivation of the exposed upper surfaces of the conductive contacts 112A-C so as to allow for sufficient deposition of the additional metal material 114A during later operations. While a gradual bottom-up fill caused by differential passivation is desirable to avoid premature closing of the conductive contacts 112A-C and formation of a seam in the conductive contacts 112A-C, excessive passivation may result in unfilled features, which may not be desirable or acceptable. For example, over-passivation may be avoided by performing an initial tungsten deposition process to partially fill the contact opening, followed by performing a brief etching process and thereafter performing an additional tungsten deposition. In some cases, while some passivation near the conductive contacts 112A-C is desirable, over-passivation may be avoided.

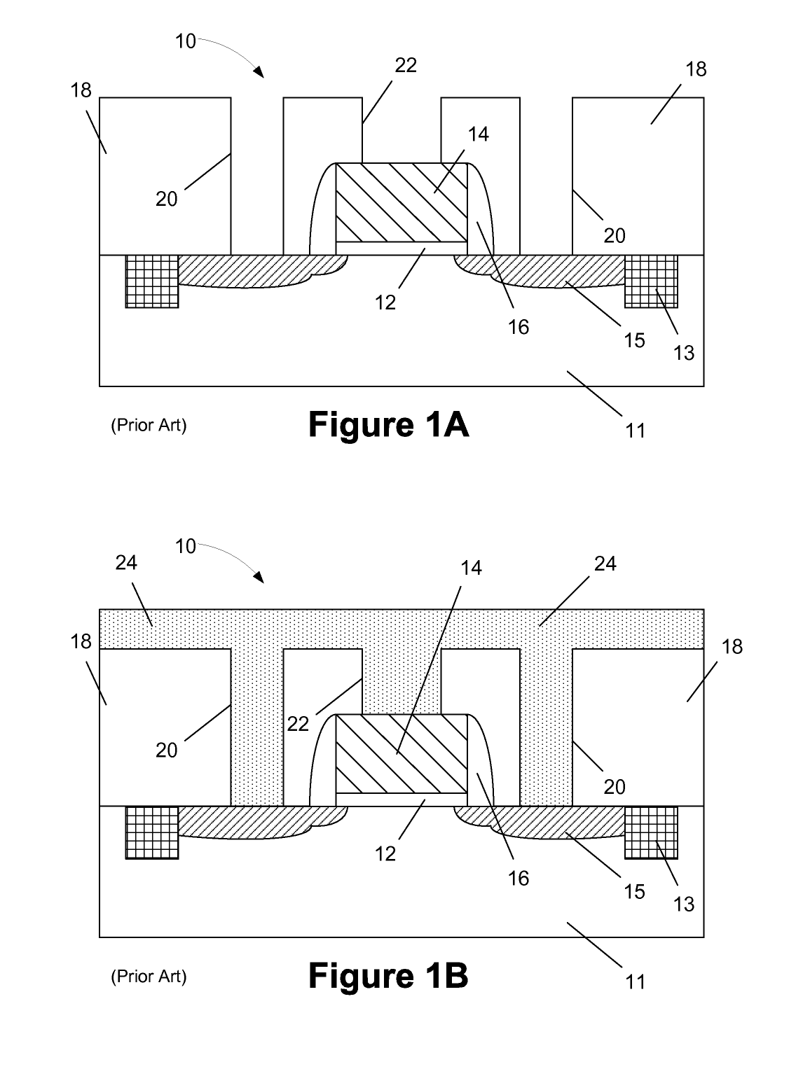

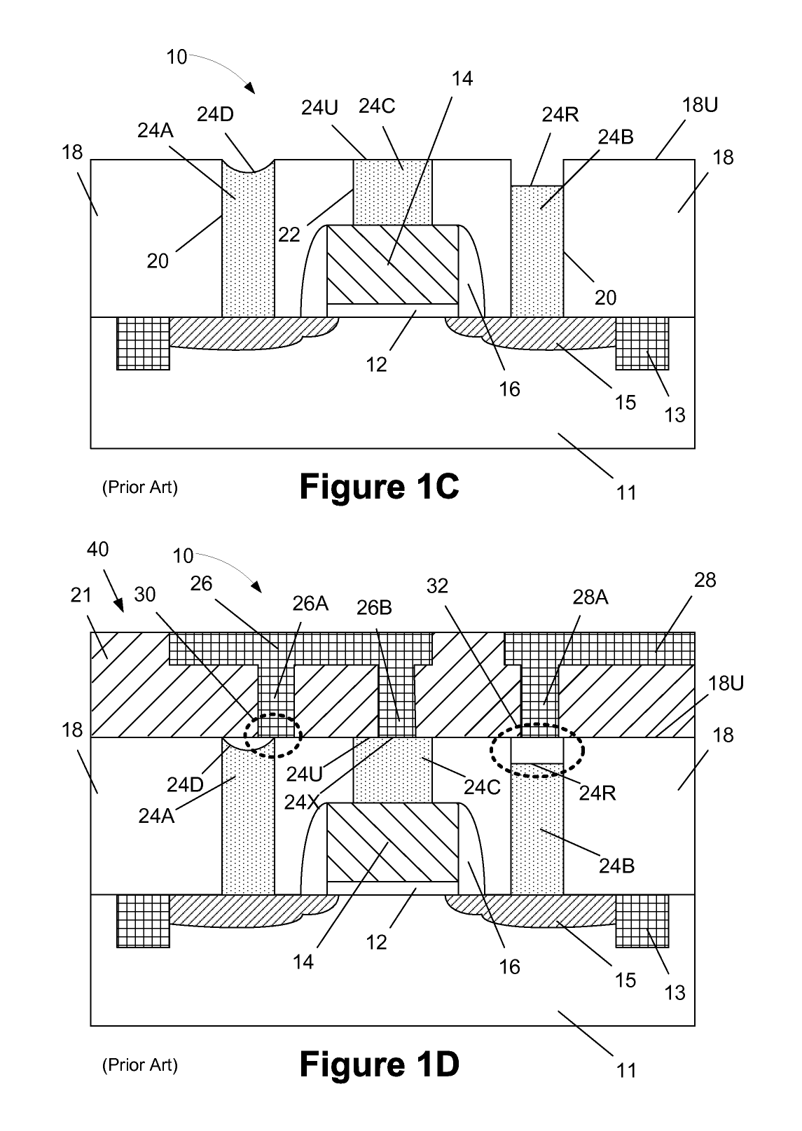

Next, as shown in FIG. 2E, a metallization layer 140 is formed above the device 100 in a layer of insulating material 121. The metallization layer 140 is generally comprised of illustrative conductive structures 126 and 128 that may be made of a variety of different materials, e.g., copper, tungsten, aluminum, etc., that are formed in the layer of insulating material 121 using traditional techniques, e.g., damascene techniques. In the depicted example, the conductive structure 126 has first and second portions (or vias) 126A, 126B that are adapted to be conductively coupled to the contacts 112A, 112B, respectively, while the conductive structure 128 has a first portion (or via) 128A that is adapted to be conductively coupled to the contact 112C. The via 126A is depicted as being slightly misaligned with the contact 112A in the region 130. However, due to the regions of additional metal material 114A formed above the originally dished contact 112A, the interface or connection between the via 126A and the contact 112A is much more robust and effective and the interface between these two conductive members is much more like the type of connection that is anticipated by the design process. That is, the interface connection 130 shown is FIG. 2D is much more desirable and reliable than the illustrative weak interface 30 described in connection with FIG. 1D above. In the case of the contact 112C that had a recessed surface 112R (see FIG. 2C), the regions of additional metal material 114A formed on the contact 112C enables conductive contact between the via 128A and the conductive contact 112C, i.e., the region of additional metal material 114A helps to avoid the open contact situation in the regions 32 that was discussed above with reference to FIG. 1D.

FIG. 3 depicts one illustrative example disclosed herein wherein the additional metal material 114A described above may be formed on illustrative conductive contacts that are formed to establish electrical connection to various portions of an illustrative transistor device 200. The transistor 200 is intended to be representative in nature. The transistor 200 is formed in an active region defined in a semiconducting substrate 211 by illustrative shallow trench isolation regions 213. In general, the transistor 200 is comprised of a gate insulation layer 212, a gate electrode 214, sidewall spacers 216 and illustrative source/drain regions 215 that are formed in the active region of the substrate 211. Of course, as will be recognized by those skilled in the art, various aspects of a real-world transistor are not depicted in FIG. 3, e.g., metal silicide regions (not shown) on the source/drain regions 115, etc. At the point of fabrication depicted in FIG. 3, a layer of insulating material 218 has been formed above the substrate 211 and a plurality of source/drain contacts 224A, 224B and a gate contact 224C has been formed in the layer of insulating material 218. The contacts 224A-C may be formed using a variety of methods such as those disclosed above in connection with the formation of the conductive contacts 112A-C. After the CMP process was performed to remove excess conductive material and thereby define the contacts 224A-C, the contact 224A has a dished surface 224D, the contact 224C has a recessed surface 224R, while the upper surface 224U of the contact 224C is substantially planar with the upper surface 218U of the layer of insulating material 218. After the contacts 224A-C are formed, the selective metal deposition process 114 described above is performed to form the regions of additional metal material 114A on the contacts 224A-C. Thereafter, a metallization layer 240 is formed above the device 200 in a layer of insulating material 221. The metallization layer 240 is generally comprised of conductive structures 226 and 228, e.g., copper, that are formed in the layer of insulating material 221 using traditional techniques, e.g., damascene techniques. In the depicted example, the conductive structure 226 has first and second portions (or vias) 226A, 226B that are adapted to be conductively coupled to the contacts 224A, 224C, respectively, while the conductive structure 228 has a first portion (or via) 228A that is adapted to be conductively coupled to the source/drain contact 224B.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a contact opening in a layer of insulating material;
forming a layer of conductive material above said layer of insulating material that overfills said contact opening;
performing at least one chemical mechanical polishing process to remove portions of said conductive material positioned outside of said contact opening and thereby define a conductive contact positioned in said contact opening; and
after performing said at least one chemical mechanical polishing process, performing a selective metal deposition process to selectively form additional metal material on an upper surface of said conductive contact.

2. The method of claim 1, further comprising forming a metallization layer above said layer of insulating material, wherein said metallization layer contains a conductive structure that is conductively coupled to said additional metal material and said conductive contact.

3. The method of claim 1, wherein said conductive contact and said additional metal material are made of the same material.

4. The method of claim 1, wherein said conductive contact and said additional metal material are made of different materials.

5. The method of claim 1, wherein said conductive contact and said additional metal material are made of aluminum, tungsten, cobalt or copper.

6. The method of claim 1, wherein a grain size of said additional metal material is larger than a grain size of a material of said conductive contact.

7. The method of claim 1, wherein said selective metal deposition process is a selective chemical vapor deposition process.

8. A method, comprising:
forming a layer of insulating material above a structure, said structure comprising s first conductive structure;
forming a contact opening in said layer of insulating material;
forming a layer of conductive material above said layer of insulating material that overfills said contact opening;
performing at least one chemical mechanical polishing process to remove portions of said conductive material positioned outside of said contact opening and thereby define a conductive contact positioned in said contact opening that is conductively coupled to said first conductive structure in said structure; and
after performing said at least one chemical mechanical polishing process, performing a selective metal deposition process to selectively form additional metal material on an upper surface of said conductive contact.

9. The method of claim 8, further comprising forming a metallization layer above said layer of insulating material, wherein said metallization layer contains a second conductive structure that is conductively coupled to said additional metal material and said conductive contact.

10. The method of claim 8, wherein said structure comprises a layer of insulating material and wherein said first conductive structure comprises a metal.

11. The method of claim 10, wherein said first conductive structure is a metal line.

12. The method of claim 8, wherein said structure is a semiconducting substrate and wherein said first conductive structure comprises a doped region formed in said substrate.

13. A device, comprising:
a first layer of insulating material;
a conductive contact positioned in said first layer of insulating material;
a region of additional metal material positioned on at least a portion of an upper surface of said conductive contact, said region of additional metal material having a rounded upper surface; and
a second layer of insulating material positioned above said first layer of insulating material.

14. The device of claim 13, further comprising a conductive structure positioned in said second layer of insulating material that is conductively coupled to said rounded upper surface of said region of additional metal material.

15. The device of claim 13, wherein a grain size of said additional metal material is larger than a grain size of a material of said conductive contact.

16. The device of claim 13, wherein said conductive contact and said region of additional metal material are made of the same material.

17. The device of claim 13, wherein said conductive contact and said region of additional metal material are made of different materials.

18. The device of claim 14, wherein said conductive contact, said conductive structure and said region of additional metal material are made of aluminum, tungsten, cobalt or copper.

19. The device of claim 14, wherein said conductive contact, said conductive structure and said region of additional metal material are made of the same material.

20. The device of claim 14, wherein said conductive contact, said conductive structure and said region of additional metal material are made of different materials.

21. A device, comprising:
a transistor comprising a gate electrode and a plurality of source/drain regions formed in a semiconducting substrate;
a first layer of insulating material formed above said gate electrode and said source/drain regions;
a plurality of source/drain conductive contacts positioned in said first layer of insulating material, each of said source/drain conductive contacts being conductively coupled to one of said source/drain regions;
a gate conductive contact positioned in said first layer of insulating material, said gate conductive contact being conductively coupled to said gate electrode;
a region of additional metal material formed on at least a portion of an upper surface of each of said plurality of source/drain conductive contacts and on at least a portion of an upper surface of said gate conductive contact, each of said regions of additional metal material having a rounded upper surface; and
a second layer of insulating material positioned above said first layer of insulating material.

22. The device of claim 21, further comprising a conductive structure positioned in said second layer of insulating material that is conductively coupled to said rounded upper surface of said region of additional metal material positioned above at least one of said plurality of source/drain conductive contacts and said gate conductive contact.

23. The device of claim 21, wherein a grain size of said additional metal material is larger than a grain size of a material of said plurality of source/drain conductive contacts and a material of said gate conductive contact.

24. The device of claim 21, wherein said plurality of source/drain conductive contacts, said gate conductive contact and said regions of additional metal material are made of the same material.

25. The device of claim 21, wherein said plurality of source/drain conductive contacts, said gate conductive contact and said regions of additional metal material are made of different materials.

26. The device of claim 21, further comprising a conductive structure positioned in said second layer of insulating material that is conductively coupled to said rounded upper surface of said region of additional metal material positioned above one of said plurality of source/drain conductive contacts and said gate conductive contact.

27. The device of claim 26, wherein said conductive structure, said plurality of source/drain conductive contacts, said gate conductive contact and said regions of additional metal material are made of the same material.

28. The device of claim 26, wherein said conductive structure, said plurality of source/drain conductive contacts, said gate conductive contact and said regions of additional metal material are made of different materials.
